(19) United States
(12) Patent Application Publication
(10) Pub. No.: US 2008/0284546 A1
(43) Pub. Date: Nov. 20, 2008

(54) BROADCAST SIGNAL RECEIVING APPARATUS

(75) Inventor: Young-ho CHOI, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/953,188

(22) Filed: Dec. 10, 2007

(30) Foreign Application Priority Data
May 14, 2007 (KR) 10-2007-0046487

(51) Int. Cl. H03J 5/00

(52) U.S. Cl. 334/1

(57) ABSTRACT

A broadcast signal receiving apparatus includes: a connecting unit through which a broadcast signal is input/output; a first tuner that is provided to be integrated with the connecting unit and tunes the broadcast signal input through the connecting unit; and a second tuner that is connected to the connecting unit via a cable and tunes the broadcast signal input through the connecting unit.

### CROSS-REFERENCE TO RELATED APPLICATIONS

This application claims priority from Korean Patent Application No. 10-2007-0046487, filed on May 14, 2007 in the Korean Intellectual Property Office, the disclosure of which is incorporated herein by reference.

### BACKGROUND OF INVENTION

1. Field of the Invention

Apparatus consistent with the present invention relates to a broadcast signal receiving apparatus, and more particularly, to a broadcast signal receiving apparatus including a plurality of tuners.

2. Description of the Related Art

A broadcast signal receiving apparatus such as a set-top box, TV or other apparatuses known in the art receives broadcast signals transmitted from broadcasting stations. With recent developments in broadcasting technologies, digital data broadcasting has been in wide use to meet the various demands of users. Digital data broadcasting refers to an interactive service using digital data. For example, a technique employed for such digital data broadcasting includes Open Cable Application Platform (OCAP) which is a data broadcasting standard platform for cable TV broadcasting.

A broadcast signal receiving apparatus that supports the digital data broadcasting may include a plurality of tuners and complicated configurations to implement the interactive service and various functions such as Picture In Picture (PIP). For example, an OCAP system has to have two tuners to implement an Out Of Band (OOB) function, an interactive DOCSIS Set-Top Gateway (DSG) function and an M-CARD Mux function to descramble two scrambled signals, and support analog broadcasting, thus having a very complex configuration.

Specifically, as shown in FIG. 1, a conventional broadcast signal receiving apparatus includes a switching box 1, a main tuner 2, a DSG tuner 3, a sub tuner 4 and a plurality of cables 5 that interconnect the above units. The switching box 1 is used to select one of a signal received through a cable broadcast signal terminal 6 and a broadcast signal received through a terrestrial broadcast signal terminal 7. For such selection, the switching box 1 has a switch control terminal 8 in which an internal switch selects one of the cable broadcast signal terminal 6 and the terrestrial broadcast signal terminal 7. A broadcast signal path may be branched to the DSG tuner 3 and the sub tuner 4. Since, in this case, the broadcast signal may have a loss in intensity, the switching box 1 includes an amplifier 9 that amplifies the broadcast signal in order to compensate for such loss. The main tuner 2 plays a role of receiving a Vestigial Side Band (VSB)/Quadrature Amplitude Modulation (QAM) signal and an OOB signal. The DSG tuner 3 is used for two-way transmission/reception of various data. The sub tuner 4 is used for a PIP function.

However, since the above various units are separated from one another in the conventional broadcast signal receiving apparatus, there are many cables 5 interconnecting these units, and these units occupy much space when they are mounted on a main circuit board. This leads to inefficient space utilization and high product costs.

In addition, as the number of tuners and cables is large, the cables may become entangled with each other and wrongly inserted.

In addition, if the cables become entangled with each other or are too closely adjacent to each other, there arises a problem of an increase in cross talk.

### SUMMARY OF THE INVENTION

Accordingly, an aspect of the present invention is a broadcast signal receiving apparatus which is capable of using a space efficiently and reducing product costs.

Another aspect of the present invention is a broadcast signal receiving apparatus which is capable of preventing cables from being entangled with each other and being wrongly inserted into ports, and is capable of reducing cross talk.

Additional aspects of the present invention will be set forth in part in the description which follows and, in part, will be obvious from the description, or may be learned by practice of the present invention.

The foregoing and/or other aspects of the present invention can be achieved by providing a broadcast signal receiving apparatus including: a connecting unit through which a broadcast signal is input/output; a first tuner that is provided to be integrated with the connecting unit and tunes the broadcast signal inputted through the connecting unit; and a second tuner that is connected to the connecting unit via a cable and tunes the broadcast signal input through the connecting unit.

According to an aspect of the invention, the broadcast signal receiving apparatus further includes a signal processing unit that processes signals input from the first tuner and the second tuner, wherein the first tuner includes a first terminal that communicates with the signal processing unit, the second tuner includes a second terminal that communicates with the signal processing unit, and at least one of the first and second terminals is not provided between the first and second tuners.

According to an aspect of the invention, the second tuner is provided in plural.

According to an aspect of the invention, the broadcast signal receiving apparatus further includes a tuner support that accommodates a plurality of second tuners, wherein the plurality of second tuners include cable connecting parts that are respectively connected to the connecting unit via the cable, and the cable connecting parts are provided at different sides of the tuner support.

According to an aspect of the invention, the plurality of second tuners include RF blocks that receive the broadcast signal through the cable connecting parts, respectively, and the RF blocks are provided so as not to be adjacent to each other in the tuner support.

According to an aspect of the invention, the second tuner is connected to a plurality of cables having different jacks.

According to an aspect of the invention, the connecting unit includes: a cable broadcast signal input part that receives a cable broadcast signal; a terrestrial broadcast signal input part that receives a terrestrial broadcast signal; and a switching unit that switches between the cable broadcast signal input part and the terrestrial broadcast signal input part.

According to an aspect of the invention, at least one of the first tuner and the second tuner includes an Open Cable Application Platform (OCAP) tuner.

According to an aspect of the invention, at least one of the first tuner and the second tuner includes a DOCSIS Set-Top Gateway (DSG) tuner.

According to an aspect of the invention, at least one of the first tuner and the second tuner includes an auxiliary tuner to accomplish a Picture In Picture (PIP) function.

According to an aspect of the invention, the first tuner is provided in plural.

### BRIEF DESCRIPTION OF THE DRAWINGS

The above and/or other aspects of the present invention will become apparent and more readily appreciated from the following description of the exemplary embodiments, taken in conjunction with the accompanying drawings, in which:

FIG. 1 is a view illustrating a conventional broadcast signal receiving apparatus;

FIGS. 2 to 5 are block diagrams illustrating a broadcast signal receiving apparatus according to an exemplary embodiment of the present invention; and

FIG. 6 is a view showing an external appearance of the broadcast signal receiving apparatus according to the exemplary embodiment of the present invention.

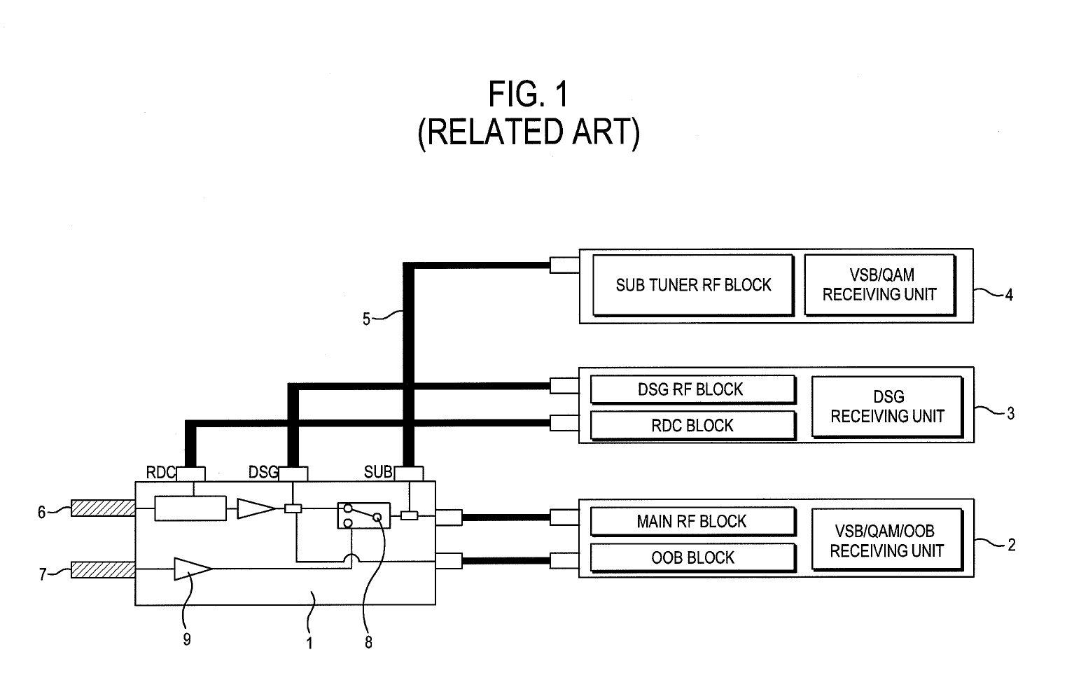

### DETAILED DESCRIPTION OF EXEMPLARY EMBODIMENTS OF THE INVENTION

Reference will now be made in detail to exemplary embodiments of the present invention, illustrated in the accompanying drawings, wherein like reference numerals refer to like elements throughout. The exemplary embodiments are described below by referring to the figures.

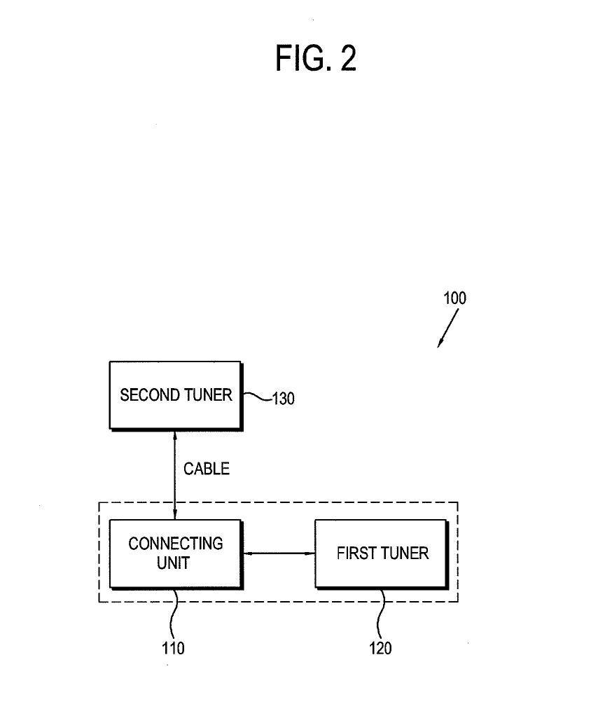

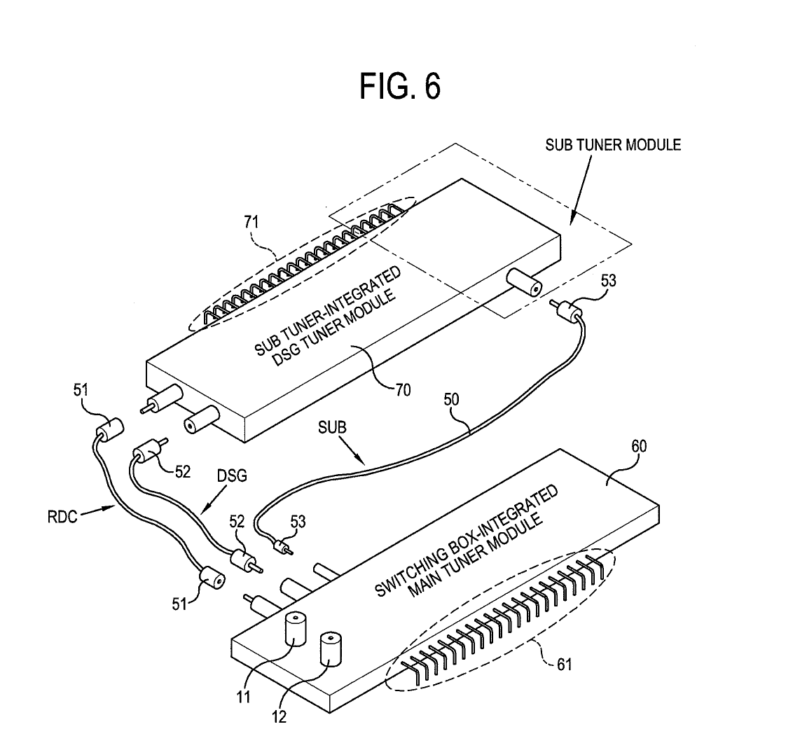

FIGS. 2 to 5 are block diagrams illustrating a broadcast signal receiving apparatus according to an exemplary embodiment of the present invention, and FIG. 6 is a view illustrating an external appearance of the broadcast signal receiving apparatus according to the exemplary embodiment of the present invention. A broadcast signal receiving apparatus 100 according to an exemplary embodiment of the present invention includes a plurality of tuners to implement digital data broadcasting and various services. For example, the broadcast signal receiving apparatus 100 may be embodied by a set-top box, a TV or other apparatuses known in the art.

As shown in FIG. 2, the broadcast signal receiving apparatus 100 includes a connecting unit 110, a first tuner 120 and a second tuner 130.

The connecting unit 110 receives and outputs broadcast signals. The connecting unit 110 receives a broadcast signal from the outside and outputs the received broadcast signal to the first and second tuners 120 and 130. The broadcast signal may include a broadcast signal and return data on the broadcast signal, which are transmitted from a broadcasting station.

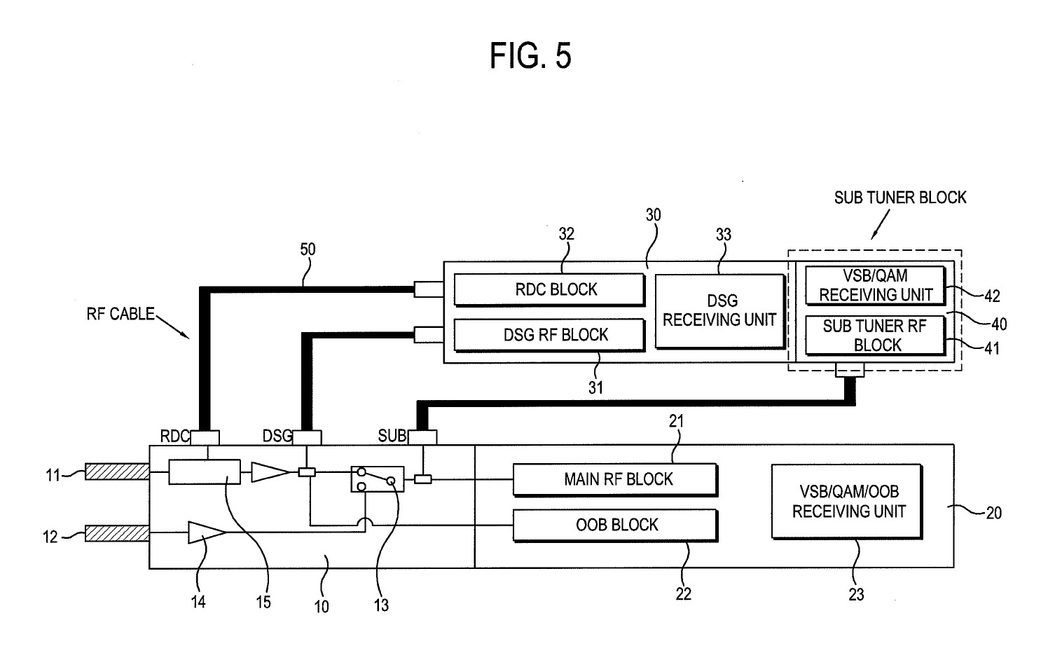

As shown in FIG. 5, the connecting unit 110 may be embodied by a switching box 10. The switching box 10 may include a cable broadcast signal input part 11 that receives a cable broadcast signal, a terrestrial broadcast signal input part 12 that receives a terrestrial broadcast signal, and a switching part 13 that switches between the cable broadcast signal input part 11 and the terrestrial broadcast signal input part 12.

In addition, the connecting unit 110 may include an amplifier 14 and a diplexer 15. The amplifier 14 amplifies an input broadcast signal to compensate for loss which may occur when the broadcast signal is branched to the first and second tuners 120 and 130. The diplexer 15 minimizes attenuation of a Reverse Data Channel (RDC) of 5 to 42 MHz and a downstream signal of a main tuner 20 or a DSG tuner 30 of 54 to 860 MHz, and separates the signals from each other without interference.

The first tuner 120 is provided to be integrated with the connecting unit 110 and tunes a broadcast signal input through the connecting unit 110. For example, the connecting unit 110 and the first tuner 120 may be interconnected by a wire on a circuit board with no cable and may be installed within a case.

As shown in FIG. 5, the first tuner 120 may be embodied by the main tuner 20. The main tuner 20 may include a main radio frequency (RF) block 21, an OOB block 22 and a VSB/QAM/OOB receiving unit 23. The main RF block 21 converts a signal transmitted with a frequency band of 54 to 860 MHz into a signal with a predetermined intermediate frequency of 44 MHz. The OOB block 22 plays a role of changing an out-of-band channel, that is, a data channel in a frequency band of 70 to 130 MHz, to an intermediate frequency of 44 MHz. The VSB/QAM/OOB receiving unit 23 plays a role of demodulating a VSB signal according to a terrestrial digital broadcast signal transmission method, a QAM signal according to a cable digital broadcast signal transmission method, and an OOB signal which is an out-of-band channel signal.

In addition, the switching box 10 and the main tuner 20 may be integrated with each other without using a cable 50, and may be embodied by a switching box-integrated main tuner module 60, as shown in FIG. 6.

In addition, the first tuner 120 may be provided to be plural in number. That is, the connecting unit 110 and a plurality of tuners may be provided to be integrated with each other. For example, the main tuner 20 and a sub tuner 40 may be mounted within a case integrated with the switching box 10.

The second tuner 130 is connected to the connecting unit 110 via a cable and tunes a broadcast signal input through the connecting unit 110. As shown in FIG. 5, the second tuner 130 may be embodied by the DSG tuner 30. The DSG tuner 30 may include a DSG RF block 31, an RDC block 32 and a DSG receiving unit 33.

At least one of the first tuner 120 and the second tuner 130 may include an OCAP tuner. As shown in FIG. 5, the OCAP tuner may be embodied by the main tuner 20 of an OCAP system.

In addition, at least one of the first tuner 120 and the second tuner 130 may include the DSG tuner 30. The DSG tuner 30 allows data to be exchanged between a transmitter and a receiver by using an internal modem in open cable broadcasting. That is, the DSG tuner 30 can provide an interactive service.

In addition, at least one of the first tuner 120 and the second tuner 130 may include an auxiliary tuner for PIP. As shown in FIG. 5, the auxiliary tuner may be embodied by the sub tuner 40. The sub tuner 40 may include a sub tuner RF block 41 and a VSB/QAM receiving unit 42.

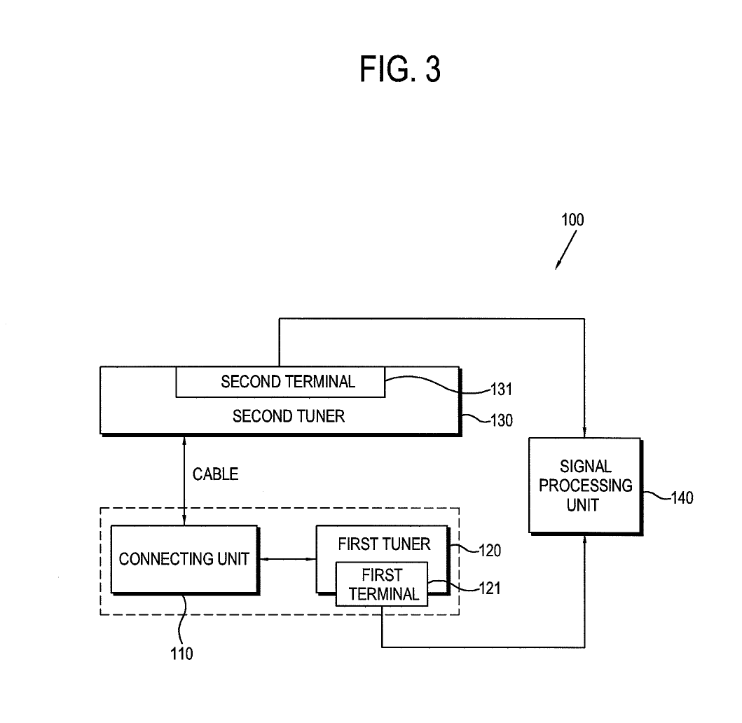

As shown in FIG. 3, the broadcast signal receiving apparatus 100 may further include a signal processing unit 140, a first terminal 121 and a second terminal 131.

The signal processing unit 140 processes signals input from the first tuner 120 and the second tuner 130. For example, the signal processing unit 140 may be provided in a main circuit board (not shown) of the broadcast signal receiving apparatus 100. If broadcast signals received in the first tuner 120 and the second tuner 130 are demodulated, decoded, and output to the signal processing unit 140, the signal processing unit 140 receives these demodulated and decoded broadcast signals and processes the received broadcast signals to be displayed as a video or image.

The first terminal 121 is provided in the first tuner 120 and communicates with the signal processing unit 140. As shown in FIG. 6, the first terminal 121 may be provided at one side of the switching box-integrated main tuner module 60 and may be mounted on the main circuit board (not shown).

The second terminal 131 is provided in the second tuner 130 and communicates with the signal processing unit 140. As shown in FIG. 6, the second terminal 131 may be provided at one side of a sub tuner-integrated DSG tuner module 70 and may be mounted on the main circuit board (not shown).

At least one of the first terminal 121 and the second terminal 131 is not provided between the first tuner 120 and the second tuner 130.

As shown in FIG. 6, a first terminal 61 is provided at one side of the switching box-integrated main tuner module 60 and a second terminal 71 is provided at one side of the sub tuner-integrated DSG tuner module 70. If the first terminal 61 is adjacent to the second terminal 71, wiring of the cables 50 becomes complex and cross talk between the first and second terminals 61 and 71 may increase. Accordingly, both of the first and second terminals 61 and 71 are arranged so as not to be located between the modules 60 and 70. Both of the first and second terminals 61 and 71 may be provided to be separated from each other as far as possible. One of the first and second terminals 61 and 71 may be arranged to be located between the modules 60 and 70, but the other should be arranged so as not to be located between the modules 60 and 70.

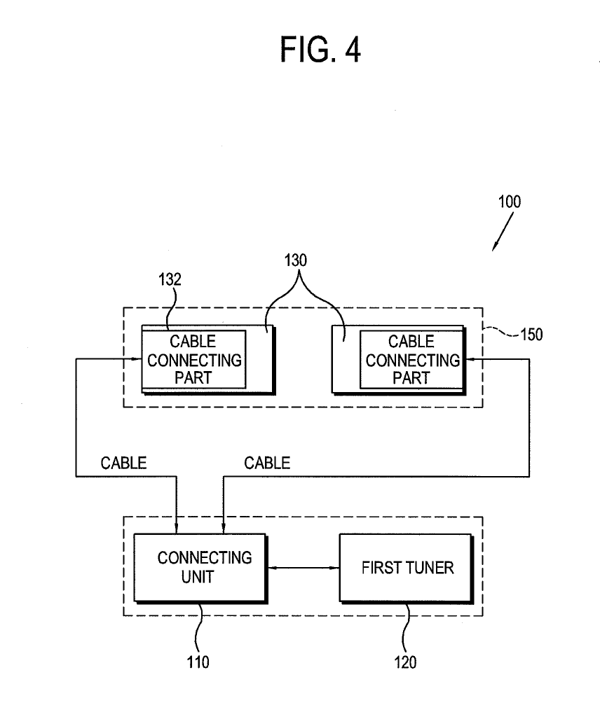

As shown in FIG. 4, the broadcast signal receiving apparatus 100 may further include a cable connecting part 132 and a tuner support 150. In addition, the second tuner 130 may be provided to be plural in number. In addition, the second tuner 130 may include the DSG tuner 30 and the sub tuner 40.

The cable connecting part 132 is provided in each of the plurality of second tuners 130 and is connected to the connecting unit 110 via a cable. For example, the plurality of second tuners 130 may be accommodated in the tuner support 150 and each may include the cable connecting part 132 for connection with the cable.

The tuner support 150 may accommodate the plurality of second tuners 130, as described above. The tuner support 150 may have a plurality of sides surrounding the plurality of second tuners 130. For example, the tuner support 150 may be embodied by an electrostatic shielding case within which the plurality of second tuners 130 is accommodated. As shown in FIG. 6, the electrostatic shielding case may be embodied by a case that accommodates the sub tuner-integrated DSG tuner module 70.

The cable connecting parts 132 may be provided in different sides of the tuner support 150. As shown in FIG. 5, if the cables 50 are connected between the switching box 10, and the DSG tuner 30 and the sub tuner 40 are adjacent to each other, the cables 50 may become entangled with each other and cross talk may increase. Accordingly, the cable connecting parts 132 may be provided at different sides of the tuner support 150 so as not to be adjacent to each other.

In addition, the plurality of second tuners 130 includes the respective RF blocks 31 and 41 that receive broadcast signals via the respective cable connecting parts 132. The RF blocks 31 and 41 may be provided in the tuner support 150 so as not to be adjacent to each other. For example, the DSG tuner 30 may include the DSG RF block 31 and the sub tuner 40 may include the sub tuner RF block 41. If the RF blocks 31 and 41 are adjacent to each other, cross talk may increase. Accordingly, the RF blocks 31 and 41 may be provided so as not be adjacent to each other.

The plurality of cables 50 connected to the second tuners 130 may have different jacks. As shown in FIG. 6, the plurality of cables 50 are connected to their respective ports between the switching box-integrated main tuner module 60 and the sub tuner-integrated DSG tuner module 70. In order to prevent the cables 50 from being wrongly inserted into the respective ports, the cables 50 may have jacks 51, 52 and 53 having different shapes. In addition, the plurality of cables 50 may have different patterns or colors.

As is apparent from the above description, one aspect of the present invention is a broadcast signal receiving apparatus which is capable of using a space efficiently and reducing product costs. In addition, another aspect is a broadcast signal receiving apparatus which is capable of preventing cables from being entangled with each other and being wrongly inserted into ports, and is capable of reducing cross talk.

Although a few exemplary embodiments of the present invention have been shown and described, it will be appreciated by those skilled in the art that changes may be made in these exemplary embodiments without departing from the principles and spirit of the invention, the scope of which is defined in the appended claims and their equivalents.

What is claimed is:

1. A broadcast signal receiving apparatus comprising:
a connecting unit through which a broadcast signal is input and output;
a first tuner integrated with the connecting unit, which tunes the broadcast signal input through the connecting unit; and
a second tuner that is connected to the connecting unit via a cable and tunes the broadcast signal input through the connecting unit.

2. The broadcast signal receiving apparatus according to claim 1, further comprising:
a signal processing unit that processes signals input from the first tuner and the second tuner;
wherein the first tuner comprises a first terminal that communicates with the signal processing unit, or
the second tuner comprises a second terminal that communicates with the signal processing unit; and
at least one of the first and second terminals is not provided between the first and second tuners.

3. The broadcast signal receiving apparatus according to claim 2, wherein the second tuner is one of a plurality of second tuners.

4. The broadcast signal receiving apparatus according to claim 3, further comprising:
a tuner support that accommodates the plurality of second tuners;
wherein the plurality of second tuners comprise cable connecting units that are respectively connected to the connecting unit via the cable; and
the cable connecting units are provided at different sides of the tuner support.

5. The broadcast signal receiving apparatus according to claim 4, wherein the plurality of second tuners comprise:
RF blocks that receive the broadcast signal through the cable connecting parts, respectively;
wherein the RF blocks are provided so as not to be adjacent to each other in the tuner support.

6. The broadcast signal receiving apparatus according to claim 1, wherein the second tuner is connected to a plurality of cables having different jacks.

7. The broadcast signal receiving apparatus according to claim 1, wherein the connecting unit comprises:
a cable broadcast signal input unit that receives a cable broadcast signal;
a terrestrial broadcast signal input unit that receives a terrestrial broadcast signal; and
a switching unit that switches between the cable broadcast signal input unit and the terrestrial broadcast signal input unit.

8. The broadcast signal receiving apparatus according to claim 1, wherein at least one of the first tuner and the second tuner comprises an Open Cable Application Platform (OCAP) tuner.

9. The broadcast signal receiving apparatus according to claim 1, wherein at least one of the first tuner and the second tuner comprises a DOCSIS Set-Top Gateway (DSG) tuner.

10. The broadcast signal receiving apparatus according to claim 1, wherein at least one of the first tuner and the second tuner comprises an auxiliary tuner which provides a Picture In Picture (PIP) function.

11. The broadcast signal receiving apparatus according to claim 1, wherein the first tuner is one of a plurality of first tuners.
